(19) United States
(12) Patent Application Publication
(10) Pub. No.: US 2011/0177650 A1
(43) Pub. Date: Jul. 21, 2011

(54) CMOS IMAGE SENSOR WITH SELF-ALIGNED PHOTODIODE IMPLANTS

(75) Inventors: Yin Qian, Milpitas, CA (US); Hsin-Chih Tai, San Jose, CA (US); Duli Mao, Sunnyvale, CA (US); Vincent Venezia, Sunnyvale, CA (US); Howard E. Rhodes, San Martin, CA (US)

(73) Assignee: OMNIVISION TECHNOLOGIES, INC., Santa Clara, CA (US)

(21) Appl. No.: 12/688,768

(22) Filed: Jan. 15, 2010

(51) Int. Cl. H01L 31/18; H01L 21/265

(52) U.S. Cl. 438/75; 438/525; 257/E21.334

(57) ABSTRACT

An example method of forming a pinned photodiode includes applying a photoresist mask to a semiconductor layer at a location where a transfer gate will subsequently be formed. First dopant ions are then implanted at a first angle to form a first dopant region under an edge of the photoresist mask. Next, a photoresist mask is etched such that a thickness of the photoresist mask is reduced to form a trimmed photoresist mask. Second dopant ions are then implanted at a second angle to form a second dopant region, wherein the second dopant ions are shadowed by the trimmed photoresist mask to exclude the second dopant ions from a region partially above the first dopant region and adjacent to an edge of the trimmed photoresist mask.

### TECHNICAL FIELD

This disclosure relates to image sensing devices, and more particularly, to the integration of pinned photodiode technology within CMOS technology.

### BACKGROUND INFORMATION

Integrated circuit implementations of imaging sensors may use active pixel arrays which have active devices, such as transistors, associated with each pixel. The active pixel sensor has the advantage of being able to incorporate both signal processing and sensing circuitry within the same integrated circuit. Conventional active pixel sensors typically employ silicon based CMOS transistor fabrication technology to form pinned photodiode sensors and adjacent transfer gates. The pinned photodiode has gained favor for its ability to have good color response for blue light, as well as advantages in dark current density and image lag. Reduction of dark current is accomplished by pinning the diode surface potential to a p type doped well or p type doped substrate (GND) through a p type doped well region. In most cases the diode is constructed in a p type doped epitaxial layer using a deep n type dopant ion implant and an additional shallow p+ type dopant ion implant above a portion of the deep n type dopant ion implanted region.

The formation of the link region between the photodiode and the transfer gate is a factor in determining how completely the signal charge is removed from the photodiode. In order to insure low noise operation, as much signal charge as possible should be evacuated from the photodiode through the link region between the photodiode and the transfer gate. When all signal charge is evacuated from the photodiode, the photodiode voltage is defined accurately at its pinned voltage. This enables noise reduction and it is a main advantage of the fully pinned photodiode over conventional photodiodes. Robust link region design and manufacture is desired for proper operation of the pinned photodiode. The link however can be very sensitive to variations in the fabrication process and in particular the lithographic alignment processes.

One approach for addressing the photodiode/transfer gate linking issue has been implemented by forming the p+ type doped pinning region adjacent to the transfer gate edge using a self-aligned shallow ion implantation process. The same transfer gate edge is then used to self-align the deep n type dopant ion implant. Often the implanted ions may be introduced at different angles in order to separate them with respect to the reference transfer gate edge. One consideration associated with the above approach is that the resulting deep n type dopant ion implant may be relatively shallow since the implant energy is limited by the thickness of the transfer gate, typically made of polysilicon, used to mask its edge. In advanced CMOS technologies the polysilicon transfer gate thickness may be reduced and thus further limit the depth to which the n type dopant ion implant may be placed. This restriction on implanted depth may limit the full well capacity of the photodiode. Deeper n type dopant ion implantation may provide higher full well capacity.

Thus, what is needed is a method of fabricating CMOS image sensors (CIS) with photodiode deep N+ implant regions that are reliably aligned with corresponding photodiode shallow P+ implant regions.

FIGS. 1A, 1B, and 1C illustrate a pinned photodiode at different stages during a conventional method of its fabrication. Such a pinned photodiode is formed within a CMOS image sensor (CIS) pixel 100 using dopant ions 150 and 160 implanted at different angles with respect to the substrate surface. FIG. 1A shows a plan view of the photodiode and transfer gate portions of single CIS pixel 100. FIGS. 1B and 1C show a cross sectional view according to cross section line X-Y indicated in FIG. 1A. Both FIGS. 1B and 1C show substrate 110 which may be a p+ type doped silicon layer having formed upon it an epitaxially grown silicon layer (epi layer) 115 which may be lightly p type doped. Within epi layer 115 may be formed doped wells 125 which may be doped at an intermediate level of p type doping. Shallow trench Isolation (STI) regions 120 are formed within doped wells 125 to electrically isolate adjacent image sensor pixels. Prior to ion implanting pinned photodiode elements, dopant regions (135 shown in FIG. 1B and 165 shown in FIG. 1C), transfer transistor gate 130 is formed for the purpose of transferring out from the pinned photodiode the photo generated carriers (signal charge) that are accumulated and held within the pinned photodiode during exposure to scene illumination. An additional preparatory step shown in FIG. 1B includes the formation of photoresist pattern 140 over a portion of gate 130 and other areas not intended to receive implanted ions 150 such as floating diode 170. Further FIG. 1C shows the formation of photoresist pattern 142 which as shown covers a portion of transfer gate 130 and other areas not intended to receive implanted ions 160 such as floating diode 170.

Referring again to FIGS. 1B and 1C, one edge of transfer gate 130 provides an ion implant masking function that allows the elements of the pinned photodiode to be aligned. Specifically pinned photodiode dopant region 135 (cathode) is formed by ion implanting n type dopant ions 150, such as Phosphorus or Arsenic, at an angle relative to the exposed vertical edge of transfer gate 130 such that dopant ions 150 may be placed a short distance under transfer gate 130. Ion implant dopant ions 150 may have high implantation energy and thereby penetrate deeper into epi forming dopant region 135. It is advantageous in terms of photodiode full well capacity to implant dopant ions 150 deeply, extending dopant region 135 further into epi layer 115. The upper limit of the implant energy may be determined largely by the thickness and crystal structure of transfer gate 130 which may be polysilicon or other typical CMOS transistor gate materials.

Continuing the conventional method, photoresist mask 140 is removed and replacement photoresist mask 142 is formed such that transfer gate 130 is again partially exposed. It is preferable that the entire periphery of dopant region 135 at the surface of epi layer 115 be exposed as well. The pinned photodiode dopant region 165 (anode) is then formed by ion implanting p type dopant ions 160, such as Boron or Indium, at an angle relative to the exposed vertical edge of transfer gate 130. Dopant ions 160 are shadowed by transfer gate 130 and thereby excluded from a small region above cathode dopant region 135 and adjacent to transfer gate 130 edge. This small region between the edges of dopant regions 135 and 165 is designated by numeral 133 on FIG. 1C. Ion implant dopant ions 160 may have low implantation energy and only penetrate to a shallow level within epi layer 115 and forming dopant region 165 as shown in FIG. 1C. Alignment and separation of the edges of dopant regions 135 and 165 is an important performance factor for image sensor pixels 100. One such performance factor is the dependence of image lag on the alignment of dopant region 165 to dopant region 135 at the edge of transfer gate 130. In this conventional method the alignment and separation depends in part on the thickness of transfer gate 130, as well as the angle and energy of both ion implants. In addition, as previously mentioned, the upper limit on implant energy for dopant ions 150 may be determined by the thickness of gate 130. One way to address this limitation is to add a process compatible layer such as silicon oxide or nitride, on top of transfer gate 130 prior to its formation in order to make it a thicker ion implant mask. This solution however adds complexity and cost to a standard CMOS fabrication process.

The alignment of dopant region 165 to dopant region 135 is not only important at the transfer gate edge. In fact, at all other locations around the periphery of the photodiode it is preferable that pinning photodiode dopant region 165 fully enclose photodiode dopant region 135, i.e., that dopant region 165 preferably extends beyond the borders of dopant region 135. Ion implant shadowing on the sides of the pixel opposite to the transfer gate produces offsets opposite to those provided at the transfer gate edge. The layout design and alignment of photoresist masks 140 and 142 preferably anticipate this in order to meet the above stated preference for placement of dopant region 135. It will be understood that the area of cathode dopant region 135 will be smaller than that of anode dopant region 165 to the extent that photomask alignment tolerances and photoresist mask shadowing effects will dictate. As CIS pixel design and fabrication technologies advance, pixel sizes decrease in order to provide more pixels per unit area. Alignment tolerances often cannot be decreased in proportion to decreases in pixel element dimensions and, in particular for the pinned photodiode pixel elements, the cathode element is made to shrink more than the anode element in order to compensate for retained alignment tolerances. This may result in an accelerated decline of the full well capacity and therefore a decline in performance of the pinned photodiode pixel.

In another conventional method that is not shown here, after dopant ions 150 have been implanted at an angle to transfer gate 130 while masked by photoresist mask 140, photoresist mask 140 is removed and a conventional gate spacer is formed on the edge of transfer gate 130. A separate photoresist mask 142 is placed on pixel 100 and dopant ions 160 are ion implanted. The gate spacer participates in the separation and alignment of the pinned photodiode regions near transfer gate 130 in this method.

FIG. 2 shows a flow chart to illustrate the sequence of fabrication steps described above in relation to FIGS. 1B and 1C. FIG. 2, step number 2.1 corresponds to FIG. 1A. In FIG. 2, step 2.2 photoresist mask 140 is applied to pixel 100 covering dopant region 125 and part of transfer gate 130 and floating diode 170. In FIG. 2 step 2.3 dopant ions 150 are implanted at an angle to place dopant region 135 under the edge of gate 130. In FIG. 2 step 2.4 photoresist mask 140 is removed and replaced by photoresist mask 142 which is placed with proper margin to expose dopant region 125 to dopant ions 160. In FIG. 2 step 2.5 ions 160 are implanted at an angle to form a shadow at the edge of transfer gate 130, and additionally Ions 160 are placed at least partially over dopant region 125. A disadvantage of such a method is the use of two photoresist masks and the potential for performance reduction due to photomask misalignment.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIGS. 1A-1C illustrate plan and cross sectional views showing one prior art fabrication sequence for a pinned photodiode and a transfer transistor of an image sensor pixel.

FIG. 2 is a flow chart illustrating a prior art fabrication sequence to achieve alignment of photodiode implants for a pinned photodiode and a transfer transistor of an image sensor pixel.

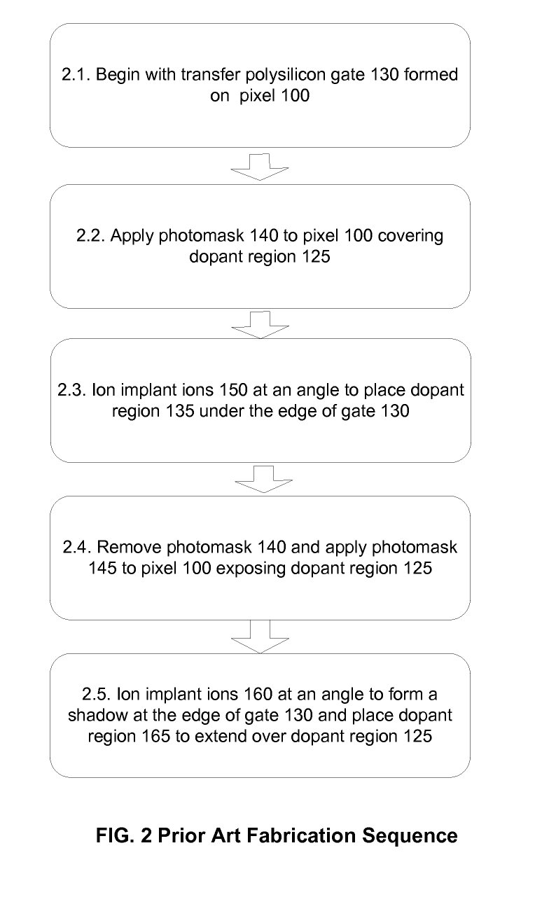

FIGS. 3A, 3B, and 3C together illustrate cross sectional views showing only the pixel photodiode and the transfer transistor and a method to achieve alignment of photodiode implants according to an embodiment of the invention.

FIG. 4 is a flow chart illustrating one fabrication sequence to achieve alignment of photodiode implants according to an embodiment of the invention.

FIGS. 5A, 5B, and 5C together illustrate cross sectional views showing only the pixel photodiode and the transfer transistor and a method to achieve alignment of photodiode implants according to an embodiment of the invention.

### DETAILED DESCRIPTION

Embodiments of an image sensor array having self-aligned pinned photodiode implants and methods for its fabrication are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

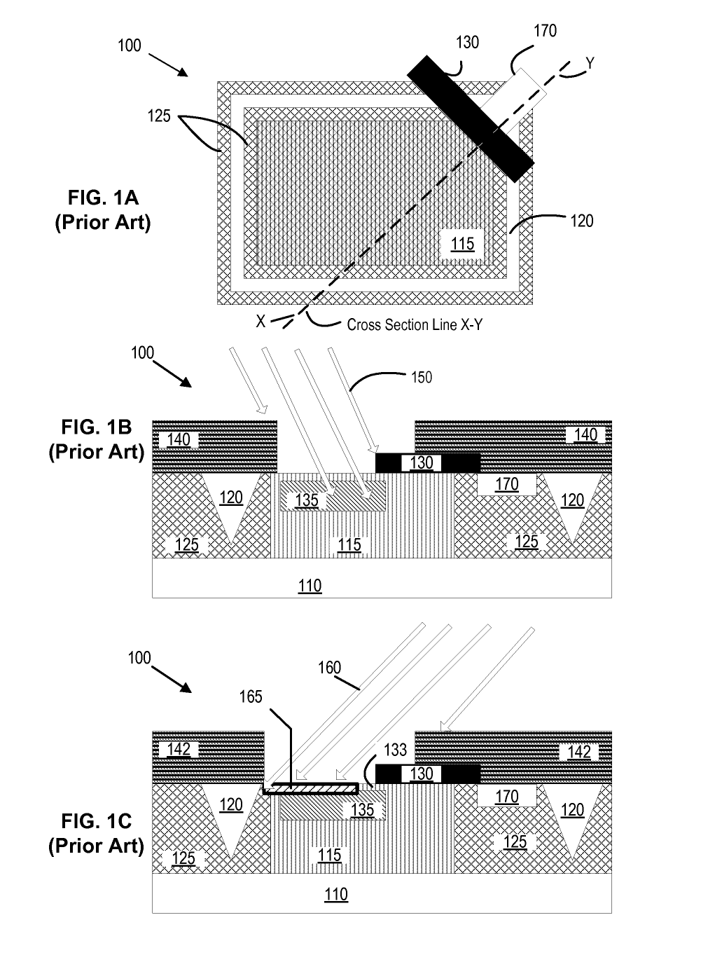

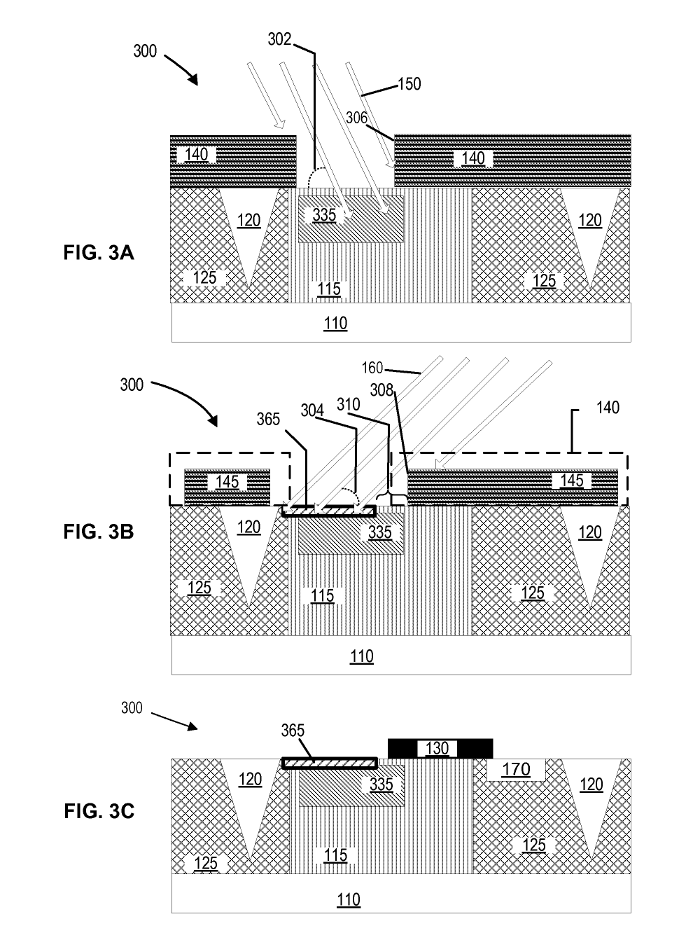

FIGS. 3A, 3B, and 3C illustrate an alternate method of fabrication of a pinned photodiode for CIS pixel 300 according to an embodiment of this disclosure. The structures shown in FIGS. 3A and 3B are similar to those shown in FIGS. 1B and 1C respectively with the exception that transfer gate 130 has not been formed yet in FIGS. 3A and 3B. In this embodiment photoresist mask 140 again defines the region intended to receive dopant ions 150. Dopant region 335 is formed using a similar angled implant placing dopant ions 150 under the edge 306 of photoresist mask 140. In one embodiment, angle 302 is a non-zero angle less than 90 degrees relative to the exposed surface of epi layer 115. Since the thickness of photoresist mask 140 can be very large compared with the limited thickness of transfer gate 130 (FIG. 1B), there is more flexibility in the choice of ion implant energy for dopant ions 150. Dopant region 335 may then extend deep into epi layer 115 and under the edge of photoresist mask 140 as partially determined by the ion implant angle 302 of dopant ions 150. Also according to this embodiment, an isotropic resist etching (resist trim) process is applied to photoresist mask 140 to reduce the thickness and other dimensions of photoresist mask 140 by a designed amount. The resulting “trimmed” photoresist mask 145 is shown in FIG. 3B with the original photoresist mask 140 shown only in dashed outline. Thus, trimmed photoresist mask 145 is self aligned to original photoresist mask 140 and therefore may require no added margin to insure dopant region 365 encloses dopant region 335. In the embodiment doped region 365 is then formed by ion implantation of dopant ions 160 at an angle 304 such that dopant ions 160 are shadowed by photoresist mask 145 and thereby excluded from a small region 310 above cathode dopant region 335 and adjacent to edge 308 of photoresist mask 145. In one embodiment, angle 304 is a non-zero angle less than 90 degrees relative to the exposed surface of epi layer 115. Subsequent fabrication steps include the formation of transfer gate 130; its edge aligned photolithographically to the previously self-aligned edges of dopant regions 335 and 365. The additional steps required for the fabrication of CIS pixels are common to the conventional embodiment and are well know and the resultant structure is shown in FIG. 3C.

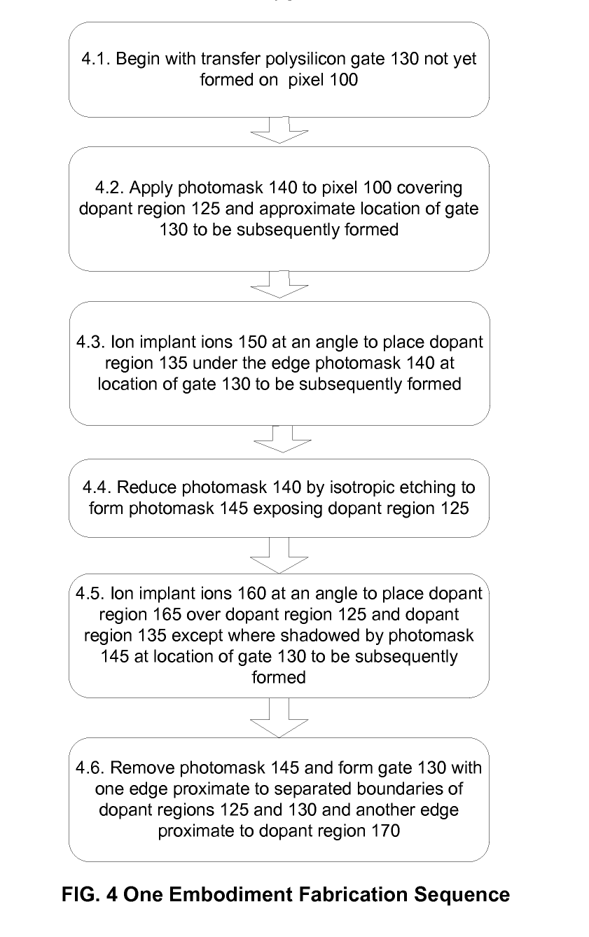

FIG. 4 shows a flow chart to illustrate the sequence of fabrication steps described above in relation to FIGS. 3A, 3B and 3C. FIG. 4 step 4.1 corresponds to FIG. 3A. FIG. 4 step 4.1 indicates a starting point wherein transfer gate 130 has not been formed yet. In FIG. 4 step 4.2 photoresist mask 140 is applied to cover all regions 125 as well as the approximate location of transfer gate 130 to be formed subsequently. In FIG. 4 step 4.3 ions 150 are implanted at an angle to place dopant region 335 under the edge of photoresist mask 140 and additionally dopant region 335 is placed inside the area of epi region 115 with spacing allowed at all points as allowed by photoresist mask 140. Without transfer gate 130 present photoresist mask 140 dopant region 335 to be placed properly relative to the future placement of transfer gate 130. In FIG. 4 step 4.4 photoresist mask 140 is “trimmed” to become photoresist mask 145 and to expose an area beyond the area of dopant region 335 previously formed. In FIG. 4 step 4.5 dopant region 365 is formed by implanting ions 160 at an angle to form a shadow at the future site of transfer gate 130 and inside dopant region 335 at that location only. Alignment of dopant region 335 to dopant region 365 within the proximity of gate 130 (to be subsequently formed) is controlled by resist trimming and implant angles as just described. In FIG. 4 step 4.6 photoresist mask 145 is removed and transfer gate 130 and floating diode 170 are formed resulting in a structure similar to that shown in FIG. 3C.

Compared to conventional methods for fabricating pinned photodiode pixels, in which two photoresist masks are required, in the disclosed embodiment the absence of an alignment tolerance allowed by self alignment of trimmed photoresist mask 145 to original photoresist mask 140 provides for a larger pinned photodiode cathode area and larger full well capacity. As noted earlier the use of a thick photoresist mask instead of the thin polysilicon gate during the ion implantation of cathode dopant ions 150 allows for the deeper placement of dopant region 335 and the potential to further increase full well capacity. Reduction of the fabrication mask count by one also reduces the cost to manufacture CMOS image sensors as well.

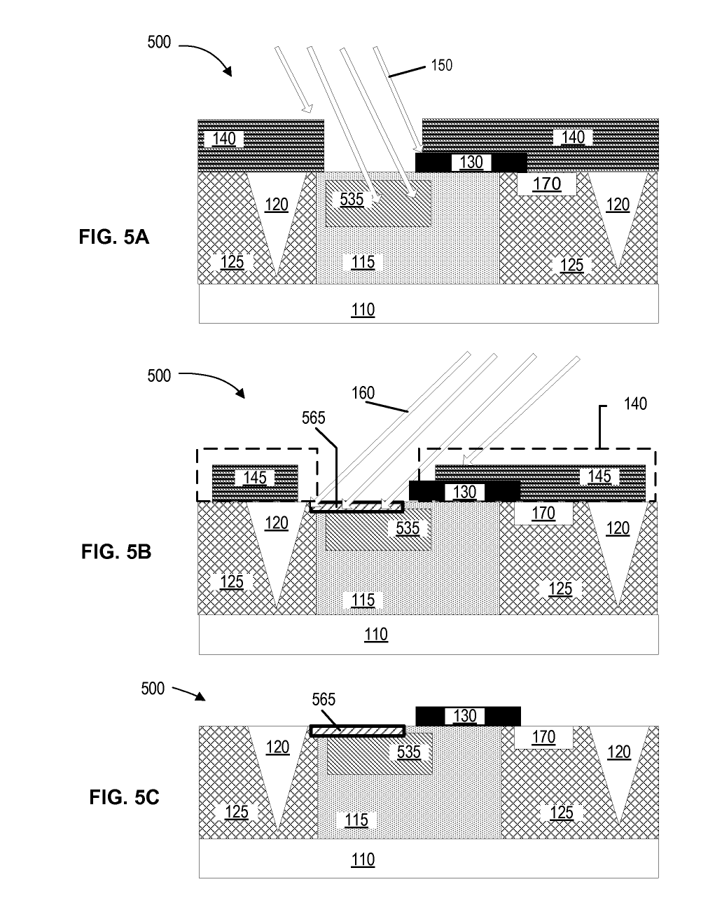

FIGS. 5A, 5B, and 5C illustrate another alternate method of fabrication of a pinned photodiode for CIS pixel 500 according to an embodiment of this disclosure. The structures shown in FIGS. 5A, 5B, and 5B are similar to those shown in FIGS. 3A, 3B, and 3C respectively in which transfer gate 130 is formed prior to the formation of the pinned photodiode elements. In this embodiment the alignment of dopant regions 535 to 565 is determined by the transfer gate edge in the region adjacent to the transfer gate as in the conventional process. The alignment of dopant regions 535 and 565 in locations other than adjacent to the transfer gate is determined by the self aligned masks as described herein. This results in reduced manufacturing cost due to fewer photoresist masks and in larger full well capacity due to a larger pinned photodiode cathode area compared to the conventionally fabricated CIS pixel.

A fabrication flow chart to fabricate this embodiment would be the same as that shown in FIG. 4 except that all steps would be applied to a structure wherein gate 130 pre-existed the steps.

It should be appreciated that the conductivity types of all the elements can be reversed such that substrate 110 is n+ doped, epi layer 115 is n doped, dopant wells 125 are n doped, doped regions 135, 335, and 535 are p doped, and doped region 165, 365, and 564 are n doped. It should also be appreciated that the formation of floating diode 170 may be accomplished before or after the formation of the pinned photodiode dopant regions.

The above description of illustrated embodiments is not intended to be exhaustive or to limit the disclosure to the precise forms disclosed. While specific embodiments and examples are described herein for illustrative purposes, various modifications are possible within the scope of the disclosure, as those skilled in the relevant art will recognize.

The order in which some or all of the process blocks appear in each process should not be deemed limiting. Rather, one of ordinary skill in the art having the benefit of the present disclosure will understand that some of the process blocks may be executed in a variety of orders not illustrated.

What is claimed is:

1. A method of forming a pinned photodiode, the method comprising:
applying a first photoresist mask to a semiconductor layer at a location where a transfer gate will subsequently be formed;
implanting first dopant ions at a first angle to form a first dopant region under an edge of the first photoresist mask;
etching the first photoresist mask such that a thickness of the first photoresist mask is reduced to form a trimmed photoresist mask; and
implanting second dopant ions at a second angle to form a second dopant region, wherein the second dopant ions are shadowed by the trimmed photoresist mask to exclude the second dopant ions from a region partially above the first dopant region and adjacent to an edge of the trimmed photoresist mask.

2. The method of claim 1, wherein the second dopant region is a pinning region of the pinned photodiode.

3. The method of claim 1, wherein the first dopant region is a cathode region of the pinned photodiode.

4. The method of claim 1, wherein etching the first photoresist mask comprises isotropic resist etching the first photoresist mask such that the trimmed photoresist mask is self aligned to the first photoresist mask.

5. A method of forming a CMOS image sensor (CIS) pixel, the method comprising:
forming a pinned photodiode of the CIS pixel by:
applying a first photoresist mask to a semiconductor layer at a location where a transfer gate will subsequently be formed;
implanting first dopant ions at a first angle to form a first dopant region under an edge of the first photoresist mask;
etching the first photoresist mask such that a thickness of the first photoresist mask is reduced to form a trimmed photoresist mask; and
implanting second dopant ions at a second angle to form a second dopant region, wherein the second dopant ions are shadowed by the trimmed photoresist mask to exclude the second dopant ions from a region partially above the first dopant region and adjacent to an edge of the trimmed photoresist mask;
removing the trimmed photoresist mask; and then
forming a polisilicon gate on the semiconductor layer above the region partially above the first dopant region.

6. The method of claim 5, wherein the second dopant region is a pinning region of the pinned photodiode.

7. The method of claim 5, wherein the first dopant region is a cathode region of the pinned photodiode.

8. The method of claim 5, wherein the polysilicon gate is a transfer gate disposed to transfer signal charge from the pinned photodiode to a floating photodiode of the CIS pixel.

9. The method of claim 5, wherein etching the photoresist mask comprises isotropic resist etching the photoresist mask such that the trimmed photoresist mask is self aligned to the photoresist mask.

10. The method of claim 5, wherein the semiconductor layer is an epitaxially grown silicon layer (epi layer), wherein the epi layer comprises a dopant well having a shallow trench isolation region to electrically isolate an adjacent CIS pixel.

11. The method of claim 10, wherein applying the first photoresist mask includes applying the first photoresist mask to the epi layer at a location where a transfer gate will subsequently be formed and at a location above the dopant well to substantially mask the dopant well from the first dopant ions.

12. The method of claim 11, wherein etching the first photoresist mask to form the trimmed photoresist mask includes etching the first photoresist mask to expose at least a portion of the dopant well such that the second dopant region extends into the dopant well after implanting the second dopant ions.

13. A method of forming a CMOS image sensor (CIS) pixel, the method comprising:
forming a polysilicon gate on a semiconductor layer; and
forming a pinned photodiode of the CIS pixel by:
applying a first photoresist mask to the polysilicon gate;
implanting first dopant ions at a first angle to form a first dopant region under an edge of the photoresist mask;
etching the first photoresist mask such that a thickness of the first photoresist mask is reduced to form a trimmed photoresist mask; and
implanting second dopant ions at a second angle to form a second dopant region, wherein the second dopant ions are shadowed by the trimmed photoresist mask to exclude the second dopant ions from a region partially above the first dopant region and adjacent to an edge of the trimmed photoresist mask.

14. The method of claim 13, wherein etching the first photoresist mask comprises isotropic resist etching the first photoresist mask such that the trimmed photoresist mask is self aligned to the first photoresist mask.

15. The method of claim 13, wherein the second dopant region is a pinning region of the pinned photodiode.

16. The method of claim 13, wherein the first dopant region is a cathode region of the pinned photodiode.

17. The method of claim 16, wherein the polysilicon gate is a transfer gate disposed to transfer signal charge from the pinned photodiode to a floating photodiode of the CIS pixel.

18. The method of claim 16, wherein the semiconductor layer is an epitaxially grown silicon layer (epi layer), wherein the epi layer comprises a dopant well having a shallow trench isolation region to electrically isolate an adjacent CIS pixel.

19. The method of claim 18, wherein etching the first photoresist mask to form the trimmed photoresist mask includes etching the first photoresist mask to expose at least a portion of the dopant well such that the second dopant region extends into the dopant well after implanting the second dopant ions.

20. The method of claim 15, wherein applying the first photoresist mask includes applying the first photoresist mask to the transfer gate and to the dopant well to substantially mask the dopant well from the first dopant ions.
